(19) United States
(12) Patent Application Publication
(10) Pub. No.: US 2026/0147047 A1
(43) Pub. Date: May 28, 2026

(54) BATTERY MODEL PARAMETER ESTIMATION APPARATUS AND METHOD THEREOF

(71) Applicants: HYUNDAI MOTOR COMPANY, Seoul (KR); KIA CORPORATION, Seoul (KR)

(72) Inventors: Yoon Sung Choi, Hwaseong-si (KR); Hyo Kyung Lee, Hwaseong-si (KR); Jae Won Kim, Hwaseong-si (KR)

(73) Assignees: HYUNDAI MOTOR COMPANY, Seoul (KR); KIA CORPORATION, Seoul (KR)

(21) Appl. No.: 19/173,967

(22) Filed: Apr. 9, 2025

(30) Foreign Application Priority Data
Nov. 28, 2024 (KR) 10-2024-0173817

(51) Int. Cl. G01R 31/367; G01R 31/392

(52) U.S. Cl. CPC G01R 31/367; G01R 31/392

(57) ABSTRACT

A battery model parameter estimation apparatus and a method thereof obtains time-series data for state information of a battery provided in a vehicle. The apparatus and method corrects a state of charge (SOC) value and a state of health (SOH) value in the time-series data. The apparatus and method predicts a model voltage corresponding to the corrected time-series data using a battery model of the vehicle. The apparatus and method estimates a parameter configured to minimize a difference between the model voltage and a real voltage as a parameter of the battery model. Thus, an optimal parameter for the battery model is estimated.

### CROSS-REFERENCE TO RELATED APPLICATION

This application claims the benefit of and priority to Korean Patent Application No. 10-2024-0173817, filed in the Korean Intellectual Property Office on Nov. 28, 2024, the entire contents of which are incorporated herein by reference.

### TECHNICAL FIELD

The present disclosure relates to technologies for estimating a parameter of a battery model provided in a vehicle to have high accuracy.

### BACKGROUND

In general, an electric vehicle is a vehicle, which drives with electric energy as power and includes a battery comprising a plurality of battery cells configured to store electric energy. Such a battery cell converts chemical energy into electrical energy to supply the electrical energy (discharging) or converts electrical energy supplied from the outside into chemical energy to store the chemical energy (charging).

Because such an electric vehicle drives with electric energy stored in the battery as a power source, the performance of the vehicle depends on the performance of the battery. Thus, to improve the performance of the electric vehicle, the battery should be managed to maximize the performance of the battery.

Recently, because a battery cell with excellent performance has been used to improve a power source of the vehicle and there has been a trend to gradually increase the number of battery cells, the need and demand for battery management has increased. Such battery management is generally performed by a battery management system (BMS).

Such a BMS measures state information of the battery provided in the electric vehicle, such as a voltage, a current, or a temperature, and manages charging and discharging of the battery using the state information and an option value for control of the battery.

In addition, the BMS may include a state of charge (SOC) estimation algorithm and a state of health (SOH) estimation algorithm, as algorithms for estimating a state of the battery. The SOC estimation algorithm and the SOH estimation algorithm mostly simulate a voltage based on a battery equivalent circuit model or simulate a voltage by directly using parameters constituting the battery equivalent circuit model.

The parameters of the battery equivalent circuit model fluctuate in a highly sensitive and non-linear manner based on several operation environments, such as a temperature or an aging state of the battery. It is difficult to normally simulate a terminal voltage due to such an environment. In other words, non-linear parameters cause deterioration in accuracy of state estimation algorithms. As a result, the non-linear parameters cause a decrease in energy efficiency, a decrease in output performance, a decrease in stability, or the like. Thus, a technology for updating the parameters of the battery equivalent circuit model in real time is applied to accurately estimate the state of the battery.

Such a technology (for updating as discussed above) extracts parameters using only a terminal voltage and a terminal current of the battery. However, as described above, because such parameters are non-linear and it is difficult to identify a dynamic characteristic, it is difficult to estimate an accurate value in real time. Thus, various studies associated with the estimation of the accurate value in real time are progressing and are roughly classified into a direct estimation scheme and a model-based adaptive filter scheme according to the logic of updating a parameter.

The direct estimation scheme is a scheme for applying a dynamic characteristic over time every moment to update a parameter, which is used to estimate a parameter (e.g., internal resistance) capable of intuitively simulating a dynamic characteristic through a variation in current and voltage. However, like internal capacitance for simulating the polarization potential of the battery, a parameter capable of being simulated based on current and voltage data measured during a certain time has a limitation to use the direction estimation scheme.

On the other hand, because the model-based adaptive filter scheme applies a filter gain by itself to reflect a past estimation result based on a recursive method to increase the accuracy of a final estimation value, it supplements the disadvantage of the direct estimation scheme. There are representatively various types of error correction algorithms, such as an extended Kalman filter (EKF) capable of being applied to a non-linear system as well as a linear system, which provides an effective estimation value for noise. The error correction algorithms also include a recursive least square (RLS) having a simple estimation process based on a correction gain for minimizing the square of an error, other than a particle filter (PF).

Because such a parameter estimation technology should reflect a past estimation result on several occasions in the process of updating the parameter, it takes considerable time to estimate an optimal parameter. Because such a parameter estimation technology estimates a parameter using only data obtained in a specific SOC interval (e.g., SOC 40% to SOC 100%) of the battery, accuracy is degraded.

Details described in the background art are intended to increase the understanding of the background of the present disclosure, which may include details rather than an existing technology well known to those having ordinary skill in the art.

### SUMMARY

The present disclosure aims to solve the above-mentioned problems occurring in the prior art while advantages achieved by the prior art are maintained intact.

An aspect of the present disclosure provides a battery model parameter estimation apparatus and a method thereof. The apparatus and the method obtain time-series data for state information of a battery provided in a vehicle. The apparatus and the method correct a state of charge (SOC) value and a state of health (SOH) value in the time-series data. The apparatus and the method predict a model voltage corresponding to the corrected time-series data using a battery model of the vehicle. The apparatus and the method estimate a parameter configured to minimize a difference between the model voltage and a real voltage as a parameter of the battery model. Thus, an optimal parameter for the battery model may be estimated.

Another aspect of the present disclosure provides a battery model parameter estimation apparatus and a method thereof. The apparatus and the method obtain time-series data for state information of a battery provided in a vehicle. The apparatus and the method determine a reference state of charge (SOC) value and a reference state of health (SOH) value based on a voltage, a current, and a temperature in the time-series data. The apparatus and the method respectively correct an SOC value and an SOH value in the time-series data based on the reference SOC value and the reference SOH value. The apparatus and the method predict a model voltage corresponding to the corrected time-series data using a battery model of the vehicle. The apparatus and the method estimate a parameter configured to minimize a difference between the model voltage and a real voltage as a parameter of the battery. Thus, an optimal parameter for the battery model may be estimated.

Another aspect of the present disclosure provides a battery model parameter estimation apparatus and a method thereof. The apparatus and the method obtain time-series data for state information of a battery provided in a vehicle. The apparatus and the method determine whether to update a parameter of a battery model of the vehicle based on a state of health (SOH) value in the time-series data. The apparatus and the method correct a state of charge (SOC) value and the SOH value in the time-series data. The apparatus and the method predict a model voltage corresponding to the corrected time-series data using the battery model. The apparatus and the method estimate a parameter for minimizing a difference between the model voltage and a real voltage as a parameter of the battery model. Thus, an optimal parameter for the battery model may be estimated.

Another aspect of the present disclosure provides a battery model parameter estimation apparatus and a method thereof. The apparatus and the method obtain time-series data for driving information of a vehicle and time-series data for state information of a battery provided in the vehicle. The apparatus and the method determine whether to update a parameter of a battery model of the vehicle based on an accumulated mileage of an odometer (ODO) provided in the vehicle in the time-series data for the driving information. The apparatus and the method correct a state of charge (SOC) value and a state of health (SOH) value in the time-series data. The apparatus and the method predict a model voltage corresponding to the corrected time-series data using the battery model of the vehicle. The apparatus and the method estimate a parameter configured to minimize a difference between the model voltage and a real voltage as a parameter of the battery model. Thus, an optimal parameter for the battery model may be estimated.

Another aspect of the present disclosure provides a battery model parameter estimation apparatus and a method thereof. The apparatus and the method obtain time-series data for state information of a battery provided in a vehicle. The apparatus and the method determine whether to update a parameter of a battery model of the vehicle based on an update request signal from a battery management system (BMS) provided in the vehicle. The apparatus and the method correct a state of charge (SOC) value and a state of health (SOH) value in the time-series data. The apparatus and the method predict a model voltage corresponding to the corrected time-series data using the battery model. The apparatus and the method estimate a parameter configured to minimize a difference between the model voltage and a real voltage as a parameter of the battery model. Thus, an optimal parameter for the battery model may be estimated.

The purposes of the present disclosure are not limited to the aforementioned purposes. Any other purposes and advantages not mentioned herein should be clearly understood from the following description and may more clearly known by an embodiment of the present disclosure. Furthermore, it may be easily seen that purposes and advantages of the present disclosure may be implemented by means indicated in claims and a combination thereof.

According to an aspect of the present disclosure, a battery model parameter estimation apparatus may include storage configured to store a battery model of a vehicle and may include a controller. The controller obtains time-series data for state information of a battery provided in the vehicle. The controller corrects a state of charge (SOC) value and a state of health (SOH) value in the time-series data. The controller predicts a model voltage corresponding to the corrected time-series data based on the battery model. The controller estimates a parameter configured to minimize a difference between the model voltage and a real voltage as an optimal parameter of the battery model.

In an embodiment of the present disclosure, the controller may determine a reference SOC value and a reference SOH value based on the time-series data. The controller may correct the SOC value using the reference SOC value. The controller may correct the SOH value using the reference SOH value.

In an embodiment of the present disclosure, the controller may determine whether to update the parameter of the battery model based on the SOH value.

In an embodiment of the present disclosure, the controller may obtain time-series data for driving information of the vehicle. The controller may determine whether to update the parameter of the battery model based on an accumulated mileage in the time-series data for the driving information.

In an embodiment of the present disclosure, the controller may determine whether to update the parameter of the battery model based on an update request signal from the vehicle.

In an embodiment of the present disclosure, the state information of the battery may include at least one of an SOC, an SOH, a current, a voltage, or a temperature.

In an embodiment of the present disclosure, the battery model may be a model configured to predict a voltage based on a parameter, an SOC, an SOH, a current, and a temperature.

In an embodiment of the present disclosure, the controller may remove error data from the time-series data.

In an embodiment of the present disclosure, the controller may load driving information and state information of the battery. The driving information and the state information are received from the vehicle, for each time. The controller may generate time-series data for the driving information of the vehicle and the time-series data for the state information of the battery provided in the vehicle.

According to another aspect of the present disclosure, a battery model parameter estimation method may include storing, by a storage, a battery model of a vehicle. The method may include obtaining, by a controller, time-series data for state information of a battery provided in the vehicle. The method may include correcting, by the controller, a state of charge (SOC) value and a state of health (SOH) value in the time-series data. The method may include predicting, by the controller, a model voltage corresponding to the corrected time-series data based on the battery model. The method may include estimating, by the controller, a parameter configured to minimize a difference between the model voltage and a real voltage as an optimal parameter of the battery model.

In an embodiment of the present disclosure, correcting the SOC value and the SOH value may include determining a reference SOC value and a reference SOH value based on the time-series data. Correcting the SOC value and the SOH value may include correcting the SOC value using the reference SOC value. Correcting the SOC value and the SOH value may also include correcting the SOH value using the reference SOH value.

In an embodiment of the present disclosure, obtaining the time-series data may include determining whether to update the parameter of the battery model based on the SOH value.

In an embodiment of the present disclosure, obtaining the time-series data may include obtaining time-series data for driving information of the vehicle and determining whether to update the parameter of the battery model based on an accumulated mileage in the time-series data for the driving information.

In an embodiment of the present disclosure, obtaining the time-series data may include determining whether to update the parameter of the battery model based on an update request signal from the vehicle.

In an embodiment of the present disclosure, the state information of the battery may include at least one of an SOC, an SOH, a current, a voltage, or a temperature.

In an embodiment of the present disclosure, the battery model may be a model configured to predict a voltage based on a parameter, an SOC, an SOH, a current, and a temperature.

In an embodiment of the present disclosure, obtaining the time-series data may include removing error data from the time-series data.

In an embodiment of the present disclosure, obtaining the time-series data may include loading driving information and state information of the battery. The driving information and the state information are received from the vehicle, for each time. Obtaining the time-series data may include generating time-series data for the driving information of the vehicle and the time-series data for the state information of the battery provided in the vehicle.

### BRIEF DESCRIPTION OF THE DRAWINGS

The above and other objects, features, and advantages of the present disclosure should be more apparent from the following detailed description taken in conjunction with the accompanying drawings:

FIG. 1 is a configuration diagram for a battery model parameter estimation system according to an embodiment of the present disclosure;

FIG. 2 is a configuration diagram for a battery model parameter estimation apparatus according to an embodiment of the present disclosure;

FIG. 3 is a drawing illustrating a state of charge (SOC) obtained by a controller provided in a battery model parameter estimation apparatus and a reference SOC value according to an embodiment of the present disclosure;

FIG. 4 is a drawing illustrating the result of correcting an SOC value in a controller provided in a battery model parameter estimation apparatus according to an embodiment of the present disclosure;

FIG. 5 is a drawing illustrating a process of determining a parameter of a battery model in a controller provided in a battery model parameter estimation apparatus according to an embodiment of the present disclosure;

FIG. 6 is a drawing illustrating the result of tuning a parameter of a battery model in a controller provided in a battery model parameter estimation apparatus according to an embodiment of the present disclosure;

FIG. 7 is a flowchart for a battery model parameter estimation method according to an embodiment of the present disclosure; and

FIG. 8 is a block diagram illustrating a computing system for executing a battery model parameter estimation method according to an embodiment of the present disclosure.

### DETAILED DESCRIPTION

Hereinafter, embodiments of the present invention are described in detail with reference to the accompanying drawings. In adding the reference numerals to the components of each drawing, it should be noted that the identical or equivalent components are designated by the identical numerals even when the components are displayed on other drawings. Further, in describing the embodiments of the present disclosure, a detailed description of well-known features or functions has been omitted in order not to unnecessarily obscure the gist of the present disclosure.

In describing the components of the embodiment of the present disclosure, terms, such as first, second, “A”, “B”, (a), (b), and the like, may be used. These terms are only used to distinguish one component from another component and do not limit the corresponding components irrespective of the order or priority of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary should be interpreted as having meanings equal to the contextual meanings in the relevant field of art. The terms should not be interpreted as having ideal or excessively formal meanings unless clearly defined as having such in the present application. When a controller, module, component, device, element, part, unit, or the like of the present disclosure is described as having a purpose or performing an operation, function, or the like, the controller, module, component, device, element, part, unit, or the like should be considered herein as being “configured to” meet that purpose or to perform that operation or function. Each controller, module, component, device, element, part, unit, and the like may separately embody or be included with a processor and a memory, such as a non-transitory computer readable media, as part of the apparatus.

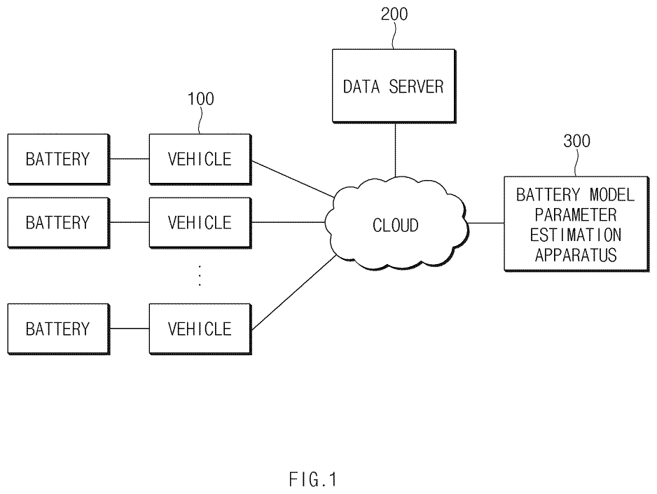

FIG. 1 is a configuration diagram for a battery model parameter estimation system according to an embodiment of the present disclosure.

As shown in FIG. 1, the battery model parameter estimation system according to an embodiment of the present disclosure may include a plurality of vehicles 100, a data server 200, and a battery model parameter estimation apparatus 300. The data server 200 may be implemented by merging into the battery model parameter estimation apparatus 300.

The vehicle 100 may include a battery management system (BMS) and may transmit driving information and state information of a battery to the data server 200. Herein, the vehicle 100 may transmit the driving information and the state information of the battery to the data server 200 in the entire state of charge (SOC) interval (e.g., 10% to 100%) of the battery while driving. The driving information may include accumulated mileage information, information indicating whether the vehicle 100 is parking or driving, information indicating whether the vehicle 100 is being charged, information indicating whether the vehicle 100 is being slow or fast charged, charging state information, or the like.

The data server 200 may be implemented as a cloud server to load driving information and state information of the battery, which are received from the vehicle 100, for each time unit or value (i.e., each time instance or time interval) for a period of time. The data server 200 may generate time-series data for the driving information of the vehicle 100 and time-series data for the state information of the battery provided in the vehicle 100 for the period of time. Such a function of the data server 200 may be implemented to be performed by the battery model parameter estimation apparatus 300.

The battery model parameter estimation apparatus 300 may obtain the time-series data for the state information of the battery provided in the vehicle 100 from the data server 200. The battery model parameter estimation apparatus 300 may correct a state of charge (SOC) value and a state of health (SOH) value in the time-series data. The battery model parameter estimation apparatus 300 may predict a model voltage corresponding to the corrected time-series data using a battery model of the vehicle 100. The battery model parameter estimation apparatus 300 may estimate a parameter for minimizing a difference between the model voltage and a real voltage as an optimal parameter of the battery model.

The battery model parameter estimation apparatus 300 may obtain time-series data for the state information of the battery provided in the vehicle 100. The battery model parameter estimation apparatus 300 may determine a reference SOC value and a reference SOH value based on a voltage, a current, and a temperature in the time-series data. The battery model parameter estimation apparatus 300 may respectively correct an SOC value and an SOH value in the time-series data based on the reference SOC value and the reference SOH value. In other words, the battery model parameter estimation apparatus 300 may correct the SOC value in the time-series data to follow the reference SOC value and may correct the SOH value in the time-series data to follow the reference SOH value.

The battery model parameter estimation apparatus 300 may obtain time-series data for the state information of the battery provided in the vehicle 100 from the data server 200. The battery model parameter estimation apparatus 300 may determine whether to update a parameter of the battery model of the vehicle 100 based on the SOH value in the time-series data.

The battery model parameter estimation apparatus 300 may obtain time-series data for the driving information of the vehicle 100 from the data server 200. The battery model parameter estimation apparatus 300 may determine whether to update a parameter of the battery model of the vehicle 100 based on the accumulated mileage of an odometer (ODO) provided in the vehicle 100 in the time-series data for the driving information.

The battery model parameter estimation apparatus 300 may determine whether to update the parameter of the battery model of the vehicle 100 based on an update request signal from the BMS provided in the vehicle 100.

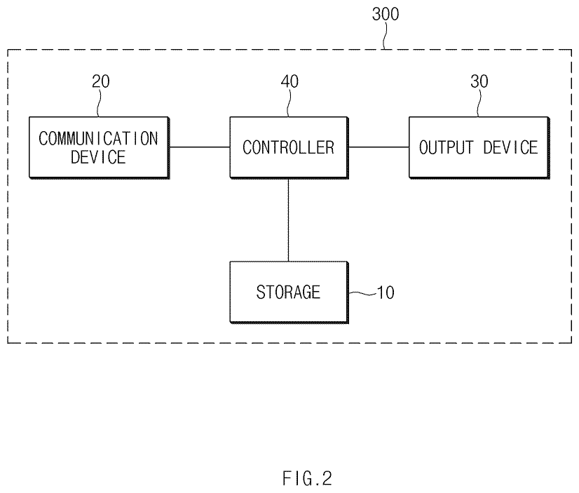

FIG. 2 is a configuration diagram for a battery model parameter estimation apparatus according to an embodiment of the present disclosure.

As shown in FIG. 2, a battery model parameter estimation apparatus 300 according to an embodiment of the present disclosure may include storage 10 (i.e., a storage device), a communication device 20, an output device 30, and a controller 40. In this case, respective components may be coupled to each other to be implemented as one according to a scheme, which executes the battery model parameter estimation apparatus 300 according to an embodiment of the present disclosure, and some components may be omitted.

The storage 10 may store various logic, algorithms, and programs required in a process of obtaining time-series data for state information of a battery provided in a vehicle 100. The logic, algorithms, and programs are required in processes of correcting an SOC value and an SOH value in the time-series data, predicting a model voltage corresponding to the corrected time-series data using a battery model of the vehicle 100, and estimating a parameter for minimizing a difference between the model voltage and a real voltage as a parameter of the battery model.

The storage 10 may store various logic, algorithms, and programs required in a process of obtaining time-series data for state information of the battery provided in the vehicle 100. The logic, algorithms, and programs are required in a process of determining a reference SOC value and a reference SOH value based on a voltage, a current, and a temperature in the time-series data. The logic, algorithms, and programs are also required in processes of respectively correcting an SOC value and an SOH value in the time-series data based on the reference SOC value and the reference SOH value, predicting a model voltage corresponding to the corrected time-series data using the battery model of the vehicle 100, and estimating a parameter for minimizing a difference between the model voltage and a real voltage as a parameter of the battery model.

The storage 10 may store various logic, algorithms, and programs required in a process of obtaining time-series data for state information of the battery provided in the vehicle 100. The logic, algorithms, and programs are required in processes of determining whether to update a parameter of the battery model of the vehicle 100 based on an SOH value in the time-series data, correcting an SOH value and the SOH value in the time-series data, predicting a model voltage corresponding to the corrected time-series data using the battery model, and estimating a parameter for minimizing a difference between the model voltage and a real voltage as a parameter of the battery model.

The storage 10 may store various logic, algorithms, and programs required in a process of obtaining time-series data for driving information of the vehicle 100 and time-series data for state information of the battery provided in the vehicle 100. The logic, algorithms, and programs are required in a process of determining whether to update a parameter of the battery model of the vehicle 100 based on an accumulated mileage of an ODO provided in the vehicle 100 in the time-series data for the driving information. The logic, algorithms, and programs are also required in processes of correcting an SOC value and an SOH value in the time-series data, predicting a model voltage corresponding to the corrected time-series data using the battery model of the vehicle 100, and estimating a parameter for minimizing a difference between the model voltage and a real voltage as a parameter of the battery model.

The storage 10 may store various logic, algorithms, and programs required in a process of: obtaining time-series data for state information of the battery provided in the vehicle 100; determining whether to update a parameter of the battery model of the vehicle 100 based on an update request signal from a BMS provided in the vehicle 100; correcting an SOC value and an SOH value in the time-series data; predicting a model voltage corresponding to the corrected time-series data using the battery model; and estimating a parameter for minimizing a difference between the model voltage and a real voltage as a parameter of the battery model.

The storage 10 may include an algorithm for calculating an SOC value based on a voltage, a current, and a temperature of the battery and an algorithm for calculating an SOH value based on a voltage, a current, and a temperature of the battery. For reference, as such algorithms are a well-known technology, a detailed description thereof has been omitted.

The storage 10 may store a battery model of each of the vehicles 100 and a parameter of the battery model of each of the vehicles 100, which is estimated by the controller 40. Herein, the battery model may predict a voltage of the battery based on the state information of the battery and the parameter. The state information of the battery may include an SOC, an SOH, a temperature, a current, a voltage, or the like.

The communication device 20 may be a module for providing a communication interface with the vehicle 100 and a communication interface with a data server 200. The data server 200 may receive a parameter update signal from a BMS of the vehicle 100. The data server 200 may receive time-series data for driving information of the vehicle 100 and time-series data for state information of the battery provided in the vehicle 100 from the data server 200. The data server 200 may transmit the parameter of the battery model, which is estimated by the controller 40, to the vehicle 100. Such a communication device 20 may include at least one of a mobile communication module, a wireless Internet module, or a short range communication module.

The mobile communication module may communicate with the vehicle 100 and the data server 200 over a mobile communication network established according to technical standards for mobile communication or a communication scheme (e.g., global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), or the like).

The wireless Internet module may be a module for wireless Internet access, which may communicate with the vehicle 100 and the data server 200 through wireless LAN (WLAN), wireless-fidelity (Wi-Fi), Wi-Fi Direct, digital living network alliance (DLNA), wireless broadband (WiBro), world interoperability for microwave access (WiMAX), high speed downlink packet access (HSDPA), high speed uplink packet access (HSUPA), long term evolution (LTE), long term evolution-advanced (LTE-A), or the like.

The short-range communication module may support short-range communication with the vehicle 100 and the data server 200 using at least one of Bluetooth™, radio frequency identification (RFID), infrared data association (IrDA), ultra-wideband (UWB), ZigBee, near field communication (NFC), and wireless universal serial bus (USB) technologies.

The output device 30 may output the result of updating the parameter of the battery model (e.g., an increase rate compared to an initial parameter or the like).

The controller 40 may be electrically connected to the respective components and may perform the overall control such that the respective components may normally perform their own functions. Such a controller 40 may be implemented in the form of hardware, may be implemented in the form of software, or may be implemented in the form of a combination thereof. In one example, the controller 40 may be implemented as, but not limited to, a microprocessor.

The controller 40 may obtain time-series data for state information of a battery provided in the vehicle 100. The controller 40 may correct an SOC value and an SOH value in the time-series data. The controller 40 may predict a model voltage corresponding to the corrected time-series data based on a battery model of the vehicle 100. The controller 40 may estimate a parameter for minimizing a difference between the model voltage and a real voltage as an optimal parameter of the battery model. The controller 40 may manage the battery model of the vehicle 100 based on the estimated optimal parameter. The controller 40 may control the vehicle 100 based on the battery model. The controller 40 may predict a model voltage V_{model} based on Equation 1 below and may determine a parameter θ for minimizing a difference between the model voltage and a real voltage Vᵣₑₐₗ based on Equation 2 below.

$$[ Equation 1 ]$$

$${V}_{m o d e l} = f ( θ , {SOC}_{c orrected} , {SOH}_{c orrected} , Temperature , Current )$$

Herein, V_{model} refers to the model voltage, θ refers to the parameter of the battery model, SOC_{corrected} refers to the corrected SOC value, and SOH_{corrected} refers to the corrected SOH value.

$${arg min}_{θ} ( {V}_{m o d e l , θ} - {V}_{r e a l} ) \qquad [ Equation 2 ]$$

Herein, θ refers to the parameter of the battery model, V_{model} refers to the model voltage, Vᵣₑₐₗ refers to the real voltage of the battery, argmine_{θ}( ) refers to the logic for determining e for minimizing the result in parentheses.

The controller 40 may obtain time-series data for state information of the battery provided in the vehicle 100. The controller 40 may determine a reference SOC value and a reference SOH value based on a voltage, a current, and a temperature in the time-series data. The controller 40 may respectively correct an SOC value and an SOH value in the time-series data based on the reference SOC value and the reference SOH value. In other words, the controller 40 may correct the SOC value in the time-series data to follow the reference SOC value and may correct the SOH value in the time-series data to follow the reference SOH value.

The controller 40 may obtain time-series data for state information of the battery provided in the vehicle 100 and may determine whether to update a parameter of a battery model of the vehicle 100 (i.e., whether to estimate an optimal parameter) based on the SOH value in the time-series data. When the SOH value is not greater than a threshold, the controller 40 may initiate to update the parameter of the battery model of the vehicle 100. In other words, the controller 40 may initiate the process of estimating the optimal parameter of the battery model.

The controller 40 may obtain time-series data for driving information of the vehicle 100 and may determine whether to update a parameter of the battery model of the vehicle 100 based on the accumulated mileage of an odometer (ODO) provided in the vehicle 100 in the time-series data for the driving information. When the accumulated mileage is greater than the threshold, the controller 40 may initiate to update the parameter of the battery model of the vehicle 100.

The controller 40 may determine whether to update the parameter of the battery model of the vehicle 100 based on an update request signal from a BMS provided in the vehicle 100.

The controller 40 may obtain time-series data for state information of the battery provided in the vehicle 100 and may remove error data from the time-series data.

The controller 40 may obtain time-series data for driving information of the vehicle 100 and may remove error data from the time-series data.

When performing a function of the data server 200, the controller 40 may load driving information and state information of the battery, which are received from the vehicle 100, for each time unit or value and may generate time-series data for the driving information of the vehicle 100 and time-series data for the state information of the battery provided in the vehicle 100.

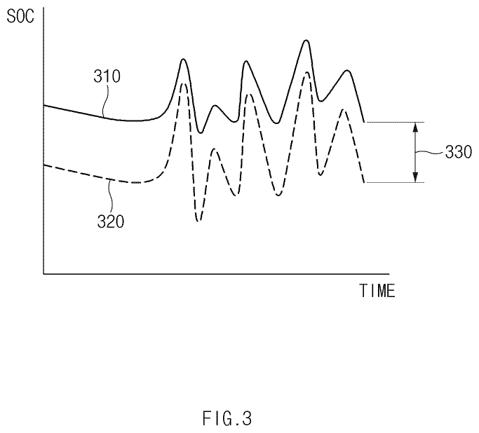

Hereinafter, the operation of the controller 40 is described in detail with reference to FIGS. 3-6.

FIG. 3 is a drawing illustrating an SOC obtained by a controller provided in a battery model parameter estimation apparatus and a reference SOC value according to an embodiment of the present disclosure.

In FIG. 3, the vertical axis indicates an SOC value, the horizontal axis indicates time, reference numeral 310 indicates an SOC value of a battery, which is obtained from a vehicle 100 by a controller 40, and reference numeral 320 indicates a reference SOC value determined based on a voltage, a current, and a temperature of the battery by the controller 40.

As shown in FIG. 3, it may be seen that a difference 330 between the SOC value 310 of the battery and the reference SOC value 320 occurs. As this occurs due to an error in a parameter according to deterioration in the battery, it is required to correct the SOC value 310 of the battery.

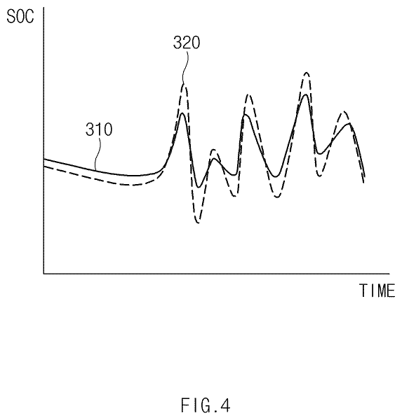

FIG. 4 is a drawing illustrating the result of correcting an SOC value in a controller provided in a battery model parameter estimation apparatus according to an embodiment of the present disclosure.

A controller 40 may correct an SOC value 310 of a battery based on Equation 1 above to follow a reference SOC value 320. As shown in FIG. 4, it may be seen that the SOC value 310 of the battery follows the reference SOC value 320.

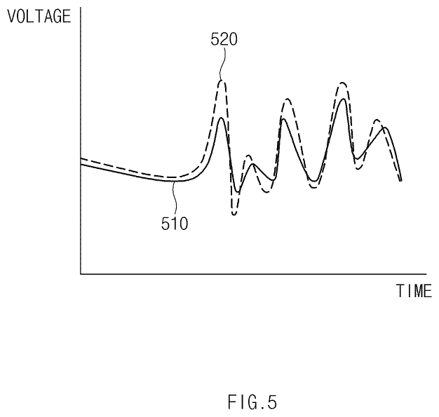

FIG. 5 is a drawing illustrating a process of determining a parameter of a battery model in a controller provided in a battery model parameter estimation apparatus according to an embodiment of the present disclosure.

In FIG. 5, the vertical axis indicates voltage, the horizontal axis indicates time, reference numeral 510 indicates a model voltage V_{model}, and reference numeral 520 indicates a real voltage Vᵣₑₐₗ.

The controller 40 may determine a parameter θ for minimizing a difference between the model voltage 510 and the real voltage 520 as an optimal parameter of the battery model based on Equation 2 above.

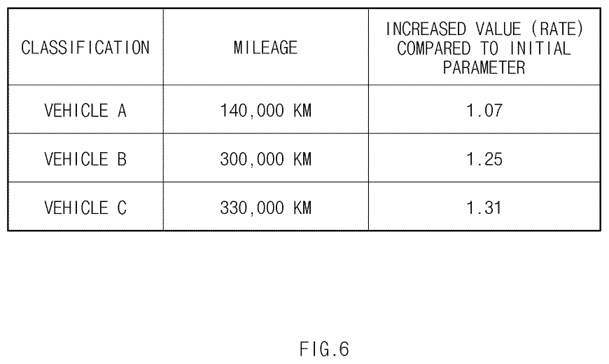

FIG. 6 is a drawing illustrating the result of tuning a parameter of a battery model in a controller provided in a battery model parameter estimation apparatus according to an embodiment of the present disclosure.

As shown in FIG. 6, vehicle A which drives 140,000 kilometers (km) has an increased rate of 1.07 compared to an initial parameter, vehicle B which drives 300,000 km has an increased rate of 1.25 compared to the initial parameter, and vehicle C which drives 330,000 km has an increased rate of 1.31 compared to the initial parameter.

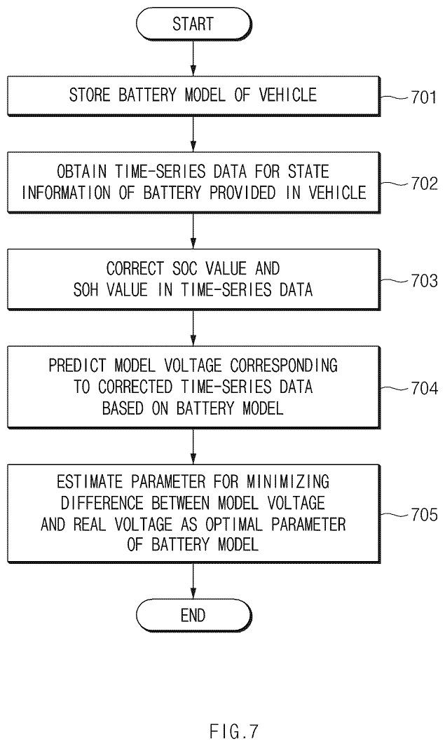

FIG. 7 is a flowchart for a battery model parameter estimation method according to an embodiment of the present disclosure.

First, in operation 701, a storage 10 may store a battery model of a vehicle 100.

Thereafter, in operation 702, a controller 40 may obtain time-series data for state information of a battery provided in the vehicle 100.

In operation 703, the controller 40 may correct an SOC value and an SOH value in the time-series data.

In operation 704, the controller 40 may predict a model voltage corresponding to the corrected time-series data based on the battery model.

In operation 705, the controller 40 may estimate a parameter for minimizing a difference between the model voltage and a real voltage as an optimal parameter of the battery model.

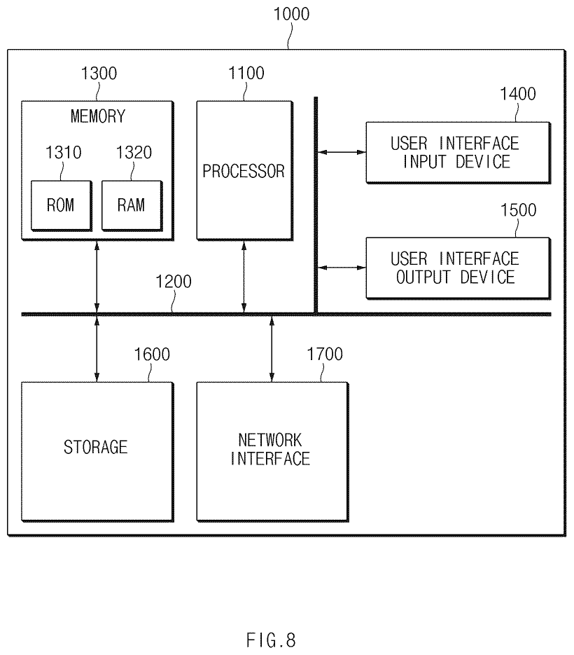

FIG. 8 is a block diagram illustrating a computing system for executing a battery model parameter estimation method according to an embodiment of the present disclosure.

Referring to FIG. 8, the above-mentioned battery model parameter estimation method according to an embodiment of the present disclosure may be implemented via a computing system 1000. The computing system 1000 may include at least one processor 1100, a memory 1300, a user interface input device 1400, a user interface output device 1500, a storage 1600 (i.e., storage device), and a network interface 1700, which are connected to each other through a system bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with the embodiments disclosed in the present disclosure may be directly implemented with a hardware module, a software module, or a combination of the hardware module and the software module, which is executed by the processor 1100. The software module may reside on a storage medium (i.e., the memory 1300 and/or the storage 1600) such as a RAM, a flash memory, a ROM, an EPROM, an EEPROM, a register, a hard disc, a removable disk, and a CD-ROM. The storage medium may be coupled to the processor 1100. The processor 1100 may read out information from the storage medium and may write information in the storage medium. Alternatively, the storage medium may be integrated with the processor 1100. The processor 110 and the storage medium may reside in an application specific integrated circuit (ASIC). The ASIC may reside within a user terminal. In another case, the processor 1100 and the storage medium may reside in the user terminal as separate components.

The battery model parameter estimation system, the battery model parameter estimation apparatus and the battery model parameter estimation method according to an embodiment of the present disclosure may obtain time-series data for state information of a battery provided in a vehicle. The system, the apparatus, and the method may correct a state of charge (SOC) value and a state of health (SOH) value in the time-series data. The system, the apparatus, and the method may predict a model voltage corresponding to the corrected time-series data using a battery model of the vehicle, and may estimate a parameter for minimizing a difference between the model voltage and a real voltage as a parameter of the battery model. Thus, an optimal parameter for the battery model may be estimated.

Hereinabove, although the present disclosure has been described with reference to embodiments and the accompanying drawings, the present disclosure is not limited thereto. Instead, the present disclosure may be variously modified and altered by those having ordinary skill in the art to which the present disclosure pertains without departing from the spirit and scope of the present disclosure claimed in the following claims. Therefore, embodiments of the present disclosure are not intended to limit the technical spirit of the present disclosure but provided only for the illustrative purpose. The scope of the present disclosure should be construed based on the accompanying claims, and all the technical ideas within the scope equivalent to the claims should be included in the scope of the present disclosure.

What is claimed is:

1. A battery model parameter estimation apparatus, comprising:
a storage configured to store a battery model of a vehicle; and
a controller configured to:
obtain time-series data for state information of a battery provided in the vehicle;
correct a state of charge (SOC) value and a state of health (SOH) value in the time-series data;
predict a model voltage corresponding to the corrected time-series data based on the battery model; and
estimate a parameter configured to minimize a difference between the model voltage and a real voltage as an optimal parameter of the battery model.

2. The battery model parameter estimation apparatus of claim 1, wherein the controller is configured to:
determine a reference SOC value and a reference SOH value based on the time-series data;
correct the SOC value using the reference SOC value; and
correct the SOH value using the reference SOH value.

3. The battery model parameter estimation apparatus of claim 1, wherein the controller is configured to:
determine whether to update the parameter of the battery model based on the SOH value.

4. The battery model parameter estimation apparatus of claim 1, wherein the controller is configured to:
obtain time-series data for driving information of the vehicle; and
determine whether to update the parameter of the battery model based on an accumulated mileage in the time-series data for the driving information.

5. The battery model parameter estimation apparatus of claim 1, wherein the controller is configured to:
determine whether to update the parameter of the battery model based on an update request signal from the vehicle.

6. The battery model parameter estimation apparatus of claim 1, wherein the state information of the battery includes at least one of an SOC, an SOH, a current, a voltage, or a temperature.

7. The battery model parameter estimation apparatus of claim 1, wherein the battery model is a model configured to predict a voltage based on a parameter, an SOC, an SOH, a current, and a temperature.

8. The battery model parameter estimation apparatus of claim 1, wherein the controller is configured to:
remove error data from the time-series data.

9. The battery model parameter estimation apparatus of claim 1, wherein the controller is configured to:
load driving information and state information of the battery, the driving information and the state information being received from the vehicle, for a period of time; and
generate time-series data for the driving information of the vehicle and the time-series data for the state information of the battery provided in the vehicle.

10. A battery model parameter estimation method, comprising:
storing, by a storage, a battery model of a vehicle;
obtaining, by a controller, time-series data for state information of a battery provided in the vehicle for a period of time;
correcting, by the controller, a state of charge (SOC) value and a state of health (SOH) value in the time-series data;
predicting, by the controller, a model voltage corresponding to the corrected time-series data based on the battery model; and
estimating, by the controller, a parameter configured to minimize a difference between the model voltage and a real voltage as an optimal parameter of the battery model.

11. The battery model parameter estimation method of claim 10, wherein correcting the SOC value and the SOH value includes:
determining a reference SOC value and a reference SOH value based on the time-series data;
correcting the SOC value using the reference SOC value; and
correcting the SOH value using the reference SOH value.

12. The battery model parameter estimation method of claim 10, wherein obtaining the time-series data includes:
determining whether to update the parameter of the battery model based on the SOH value.

13. The battery model parameter estimation method of claim 10, wherein obtaining the time-series data includes:
obtaining time-series data for driving information of the vehicle; and
determining whether to update the parameter of the battery model based on an accumulated mileage in the time-series data for the driving information.

14. The battery model parameter estimation method of claim 10, wherein obtaining the time-series data includes:
determining whether to update the parameter of the battery model based on an update request signal from the vehicle.

15. The battery model parameter estimation method of claim 10, wherein the state information of the battery includes at least one of an SOC, an SOH, a current, a voltage, or a temperature.

16. The battery model parameter estimation method of claim 10, wherein the battery model is a model configured to predict a voltage based on a parameter, an SOC, an SOH, a current, and a temperature.

17. The battery model parameter estimation method of claim 10, wherein obtaining the time-series data includes:
removing error data from the time-series data.

18. The battery model parameter estimation method of claim 10, wherein obtaining the time-series data includes:
loading driving information and state information of the battery, the driving information and the state information being received from the vehicle, for each time interval of the period of time; and
generating time-series data for the driving information of the vehicle and the time-series data for the state information of the battery provided in the vehicle.
